(19) United States
(12) Patent Application Publication
(10) Pub. No.: US 2023/0047044 A1
(43) Pub. Date: Feb. 16, 2023

(54) GALVANIC HIGH VOLTAGE ISOLATION CAPABILITY ENHANCEMENT ON REINFORCED ISOLATION TECHNOLOGIES

(71) Applicant: Texas Instruments Incorporated, Dallas, TX (US)

(72) Inventors: Elizabeth Stewart Costner, Dallas, TX (US); Jeffrey Alan West, Dallas, TX (US); Thomas Dyer Bonifield, Dallas, TX (US)

(21) Appl. No.: 17/403,723

(22) Filed: Aug. 16, 2021

(51) Int. Cl. H01L 49/02; H01G 4/30; H01L 29/06

(52) U.S. Cl. CPC H01L 28/60; H01G 4/30; H01L 29/0642

(57) ABSTRACT

A microelectronic device includes a semiconductor substrate and a high voltage isolation capacitor over the substrate. The capacitor includes a bottom capacitor plate over the substrate. Dielectric layers are formed above the bottom capacitor plate, including a top dielectric layer. A high dielectric layer on the top dielectric layer includes at least a first sublayer having a first dielectric constant that is higher than a dielectric constant of the top dielectric layer. A top capacitor plate is formed on the high dielectric layer over the bottom capacitor plate. An electric field abatement structure surrounds the top capacitor plate. The electric field abatement structure includes a shelf of the high dielectric layer extending outward from a lower corner of the bottom capacitor plate at least 14 microns, and an isolation break in the high dielectric layer past the shelf, in which the first sublayer is removed from the isolation break.

### FIELD

This disclosure relates to the field of microelectronic devices and the methods of fabrication thereof. More particularly and without limitation, this disclosure relates to a method and structure for improving high voltage breakdown reliability of microelectronic devices including, e.g., galvanic digital isolators.

### BACKGROUND

Galvanic isolation is a principle of isolating functional sections of electrical systems to prevent current flow while energy or information can still be exchanged between sections by other means, such as capacitance, induction, electromagnetic waves, optical, acoustic, or mechanical means. Galvanic isolation is typically used where two or more electric circuits communicate, but their grounds or reference nodes may be at different potentials. It is an effective method of breaking ground loops by preventing unwanted current from flowing between two units sharing a reference conductor. Galvanic isolation is also used for safety as a means of preventing accidental current from reaching ground through a person's body.

Isolators are devices designed to minimize direct current and unwanted transient currents between two systems or circuits while allowing data and power transmission between the two. In most applications, isolators also act as a barrier to high voltage in addition to allowing the system to function properly. Where capacitive elements are used as isolators, dielectric breakdown is a key concern, especially in high-voltage applications.

As the advances in the design of integrated circuits and semiconductor fabrication continue to take place, improvements in microelectronic devices, including galvanic isolators are also being concomitantly pursued.

### SUMMARY

The following presents a simplified summary in order to provide a basic understanding of one or more aspects of the present patent disclosure. The summary is not an extensive overview of the disclosure and is not intended to identify key or critical elements of the disclosure, nor is it to delineate the scope thereof. Rather, the primary purpose of the summary is to present some concepts of the disclosure in a simplified form as a prelude to a more detailed description that is present later.

Embodiments of a microelectronic device are disclosed for improving high voltage breakdown reliability of a high voltage isolation capacitor, hereinafter, the capacitor, which involve an electric field abatement structure around a top capacitor plate of the capacitor. In one aspect, the microelectronic device includes a semiconductor substrate. A bottom capacitor plate is formed over the substrate. Dielectric layers are formed above the bottom capacitor plate, including a top dielectric layer. A high dielectric layer is formed on the top dielectric layer. The high dielectric layer includes at least a first sublayer having a first dielectric constant that is higher than a dielectric constant of the top dielectric layer. A top capacitor plate is formed on the high dielectric layer. The top capacitor plate is located over the bottom capacitor plate. The dielectric layers provide a capacitor dielectric between the top capacitor plate and the bottom capacitor plate. The top capacitor plate has a lower corner contacting the high dielectric layer.

The electric field abatement structure is formed by removing the first sublayer in an isolation break of the electric field abatement structure. The isolation break is separated from the lower corner by at least 14 microns. The high dielectric layer between the isolation break and the lower corner provides a shelf of the electric field abatement structure.

### BRIEF DESCRIPTION OF THE VIEWS OF THE DRAWINGS

Embodiments of the present disclosure are illustrated by way of example, and not by way of limitation, in the Figures of the accompanying drawings in which like references indicate similar elements. It should be noted that different references to “an” or “one” embodiment in this disclosure are not necessarily to the same embodiment, and such references may mean at least one. Further, when a particular feature, structure, or characteristic is described in connection with an embodiment, it is submitted that it is within the knowledge of one skilled in the art to effect such feature, structure, or characteristic in connection with other embodiments whether or not explicitly described.

The accompanying drawings are incorporated into and form a part of the specification to illustrate one or more exemplary embodiments of the present disclosure. Various advantages and features of the disclosure will be understood from the following detailed description taken in connection with the appended claims and with reference to the attached drawing Figures in which:

FIG. 1A is a cross section of an example microelectronic device.

FIG. 1B shows a detailed view of the portion of the microelectronic device in the area of the electric field abatement structure.

FIG. 1C shows a detailed view of a portion of the microelectronic device in the area of another electric field abatement structure.

FIG. 1D shows a detailed view of a portion of the microelectronic device in the area of another example electric field abatement structure.

FIG. 2 is a Weibull chart showing TDDB for a 10 micron, 14 micron and 20 micron shelf width.

FIG. 3 is a top view of an example of the microelectronic device 100 implemented as a multi-chip module.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

Example microelectronic devices described below may include or be formed of a semiconductor material like Silicon (Si), Silicon Carbide (SiC), Silicon Germanium (SiGe), Gallium Arsenide (GaAs) or an organic semiconductor material. The semiconductor material may be embodied as a semiconductor wafer. The microelectronic devices include one or more high voltage capacitors, also referred to as galvanic isolation devices. The microelectronic devices may also include one or more semiconductor component or components such as metal oxide semiconductor field effect transistors (MOSFETs), insulated gate bipolar transistors (IGBTs) gate drivers, input/output and control circuitry, as well as microprocessors, microcontrollers, and/or micro-electro-mechanical components or systems (MEMS). The microelectronic devices may be manifested as single chip devices or may be contained in multi-chip modules (MCMs). The semiconductor chip may further include inorganic and/or organic materials that are not semiconductor, for example, insulators such as inorganic dielectric materials or polymers, or conductors such as metals.

For the purposes of this disclosure, the term “high voltage” refers to operating potentials greater than 100 volts, and “low voltage” refers to operating potentials less than 100 volts. For example, a high voltage capacitor may operate at 300 volts to 1200 volts, while a low voltage component such as a transistor may operate at 1.5 volts to 30 volts.

For the purposes of this disclosure, the “dielectric constant” of a material refers to a ratio of the material's (absolute) permittivity to the vacuum permittivity, at a frequency below 1 hertz (Hz). The vacuum permittivity has a value of approximately 8.85×10⁻¹² farads/meter (F/m).

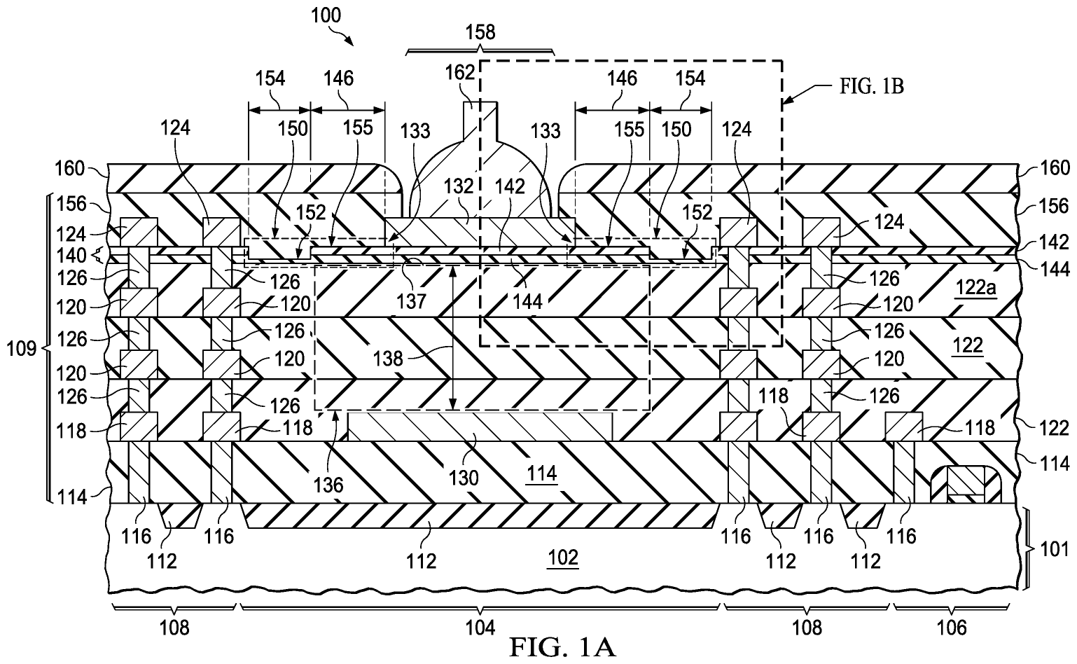

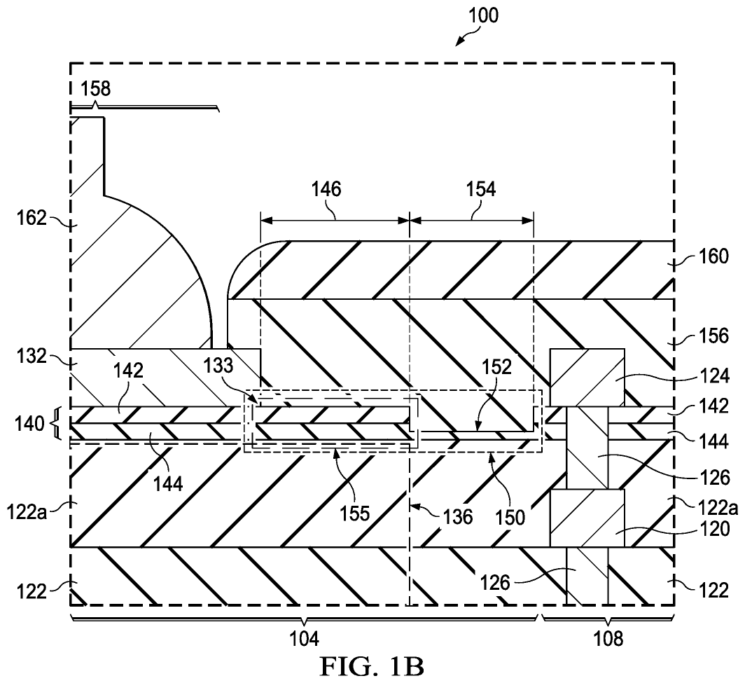

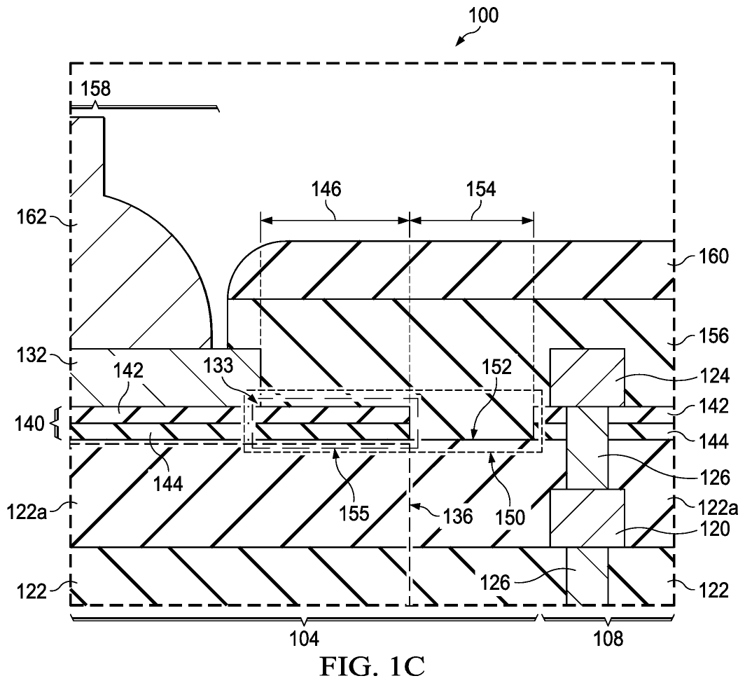

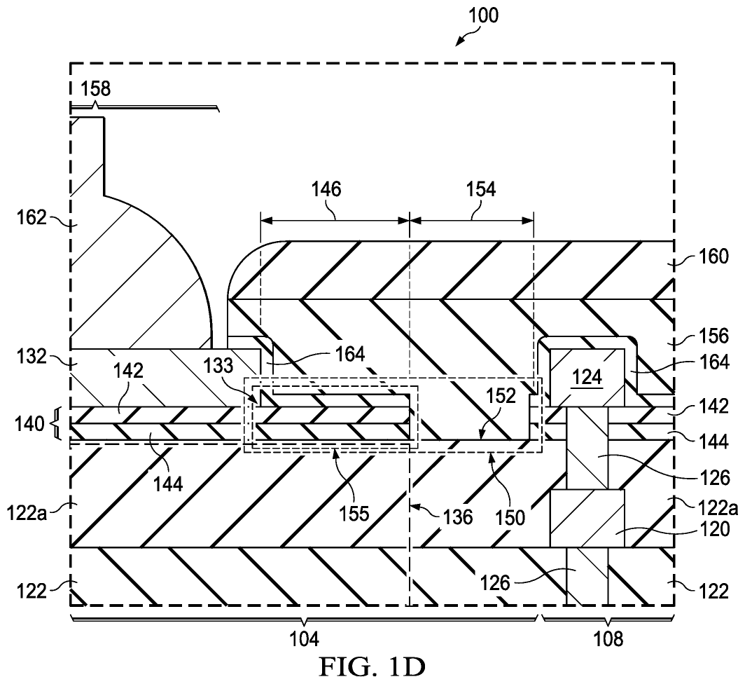

FIG. 1A is a cross section of an example microelectronic device 100. The microelectronic device 100 may be implemented as an integrated circuit, a discrete component, or a MEMS device. The microelectronic device 100 is formed on a substrate 101, which may be part of a semiconductor wafer containing additional microelectronic devices, not shown in FIG. 1A. The substrate 101 includes a semiconductor material 102. The semiconductor material 102 may include crystalline silicon, or may include another semiconductor material 102, such as silicon germanium, silicon carbide, gallium nitride, or gallium arsenide, by way of example.

Formation of the microelectronic device 100 of this example includes forming a field oxide 112 on the semiconductor material 102. The field oxide 112 may be formed by a shallow trench isolation (STI) process and have an STI structure in which the field oxide 112 is in a trench in the semiconductor material 102, as depicted in FIG. 1A. Alternatively, the field oxide 112 may be formed by a local oxidation of silicon (LOCOS) process and have a LOCOS structure, in which the field oxide 112 would have tapered edges, and extend partway into the semiconductor material 102 and extend partway above the semiconductor material 102.

One or more low voltage components 106, depicted in FIG. 1A as a MOSFET, are formed in and on the semiconductor material 102. Other manifestations of the low voltage components 106 are within the scope of this example. The low voltage components 106 may be interconnected to form circuits, or may be configured as discrete components.

After forming the low voltage components 106, an interconnect region 109 of the microelectronic device 100 is formed over the semiconductor material 102. a pre-metal dielectric (PMD) layer 114 of the interconnect region 109 is formed over the substrate 101, the field oxide 112, and the low voltage components 106. The PMD layer 114 includes one or more dielectric layers 122 of silicon dioxide, phosphosilicate glass (PSG), fluorosilicate glass (FSG), borophosphosilicate glass (BPSG), organosilicate glass (OSG), low-k dielectric material, silicon nitride, silicon oxynitride, silicon carbide, silicon carbide nitride, or other dielectric materials. The PMD layer 114 may be formed by one or more dielectric deposition processes, such as a low pressure chemical vapor deposition (LPCVD) process, a plasma enhanced chemical vapor deposition (PECVD) process, a high aspect ratio process (HARP) using ozone and tetraethyl orthosilicate (TEOS), or an atmospheric pressure chemical vapor deposition (APCVD) process.

Contacts 116 of the interconnect region 109 are formed through the PMD layer 114 to make electrical connections to the low voltage components 106 and to the semiconductor material 102. The contacts 116 are electrically conductive, and may include tungsten on a titanium adhesion layer and a titanium nitride liner. The contacts 116 may be formed by etching contact holes through the PMD layer 114, and forming the titanium adhesion layer by a physical vapor deposition (PVD) process. The titanium nitride liner may be formed on the titanium adhesion layer by an atomic layer deposition (ALD) process. The tungsten may be formed on the titanium nitride liner by a metalorganic chemical vapor deposition (MOCVD) process using tungsten hexafluoride reduced by silane and hydrogen. Tungsten, titanium nitride, and titanium on a top surface of the PMD layer 114, outside of the contacts 116, may be removed by a tungsten etchback process, a tungsten chemical mechanical polish (CMP) process, or both.

First level interconnects 118 are formed on the PMD layer 114, making electrical connections to the contacts 116. A bottom capacitor plate 130 is formed concurrently with the first level interconnects 118. The first level interconnects 118 and the bottom capacitor plate 130 are electrically conductive. In one version of this example, the first level interconnects 118 and the bottom capacitor plate 130 may have an etched aluminum structure, and may include an adhesion layer, not shown, of titanium nitride or titanium tungsten, on the PMD layer 114, an aluminum layer, not shown, with a few atomic percent of silicon, titanium, or copper, on the adhesion layer, and an anti-reflection layer, not shown, of titanium nitride on the aluminum layer. The etched aluminum interconnects may be formed by depositing the adhesion layer, the aluminum layer, and the anti-reflection layer, and forming an etch mask, not shown, followed by an RIE process to etch the anti-reflection layer, the aluminum layer, and the adhesion layer where exposed by the etch mask, and subsequently removing the etch mask. In another version of this example, the first level interconnects 118 and the bottom capacitor plate 130 may have a damascene structure, and may include a barrier liner of tantalum and tantalum nitride in an interconnect trench in an intra-metal dielectric (IMD) layer, not shown, on the PMD layer 114, with a copper fill metal in the interconnect trench on the barrier liner. The damascene interconnects may be formed by depositing the IMD layer on the PMD layer 114, and etching the interconnect trenches through the IMD layer to expose the contacts 116. The barrier liner may be formed by sputtering tantalum onto the IMD layer and exposed PMD layer 114 and contacts 116, and forming tantalum nitride on the sputtered tantalum by an ALD process. The copper fill metal may be formed by sputtering a seed layer, not shown, of copper on the barrier liner, and electroplating copper on the seed layer to fill the interconnect trenches. Copper and barrier liner metal is subsequently removed from a top surface of the IMD layer by a copper CMP process. Other processes for forming the first level interconnects 118 and the bottom capacitor plate 130 are within the scope of this example.

A plurality of dielectric layers 122 of the interconnect region 109 are formed over the PMD layer 114, the first level interconnects 118, and the bottom capacitor plate 130. The dielectric layers 122 may include IMD layers between instances of the interconnects 120 in the same level, and inter-level dielectric (ILD) layers between instances of the interconnects 120 in sequential levels. The dielectric layers 122 may include liners and cap layers of silicon nitride, silicon oxynitride, silicon carbonitride, and such. The liners and cap layers may sandwich layers of silicon dioxide-based dielectric material such as silicon dioxide with some hydrogen content, PSG, FSG, BPSG, OSG, or other low-k dielectric material. The dielectric layers 122 may be formed using processes disclosed in reference to the PMD layer 114.

Additional levels of interconnects 120 of the interconnect region 109 are formed in the dielectric layers 122. The additional levels of interconnects 120 may be formed by processes disclosed in reference to the first level interconnects 118. In further version of this example, the additional levels of interconnects 120 may have a plated structure, and may include an adhesion layer, not shown, with copper interconnects on the adhesion layer. The plated interconnects may be formed by sputtering the adhesion layer, containing titanium, on the corresponding ILD layer, followed by sputtering a seed layer, not shown, of copper on the adhesion layer. A plating mask is formed on the seed layer that exposes areas for the interconnects 120. The copper interconnects are formed by electroplating copper on the seed layer where exposed by the plating mask. The plating mask is removed, and the seed layer and the adhesion layer are removed by wet etching between the interconnects. Other processes for forming the additional levels of interconnects 120 are within the scope of this example.

Vias 126 are formed through the ILD layers of the dielectric layers 122 to make electrical connections to instances of the interconnects 120 in sequential levels. The vias 126 are electrically conductive. In one version of this example, the vias 126 may include a via liner, not shown, of titanium or titanium nitride contacting the corresponding interconnect 120, with a tungsten core, not shown, on the via liner. The vias 126 may be formed by etching via holes through the dielectric layers 122 to expose the underlying interconnects 120. The via liner may be formed by sputtering titanium followed by forming titanium nitride using an atomic layer deposition (ALD) process. The tungsten core may be formed by a metalorganic chemical vapor deposition (MOCVD) process using tungsten hexafluoride (WF₆) reduced by silane initially and hydrogen after a layer of tungsten is formed on the via liner. The tungsten, titanium nitride, and titanium is subsequently removed from a top surface of the dielectric layers 122 by an etch process, a tungsten CMP process, or a combination of both, leaving the vias 126 extending to the top surface of the interconnect 120. In another version of this example, the vias 126 may have a copper single damascene structure with a via liner of tantalum or tantalum nitride, and a copper core on the via liner. The vias 126 may be formed by a copper damascene process, in which via holes are formed through the dielectric layers 122 to expose the underlying interconnect 120. the via liner may be formed by an ALD process, and a copper seed layer may be formed on the via liner by a physical vapor deposition (PVD) process. The copper core is formed on the copper seed layer by electroplating. The copper and via liner is subsequently removed from a top surface of the interconnect 120 by a copper CMP process. In a variation of this version, the vias 126 may be formed together with the overlying interconnects 120 by a copper dual damascene process. In a further version of this example, the vias 126 may include a via liner, not shown, of titanium or titanium nitride contacting the corresponding interconnects 120, with an aluminum core, not shown, on the via liner. The vias 126 may be formed by etching via holes and forming the via liner as disclosed above. The aluminum core may be formed by a PVD process on the via liner. The aluminum, and via liner is subsequently removed from a top surface of the interconnects 120 by an etch process. Other structures and compositions for the vias 126 are within the scope of this example.

The dielectric layers 122 include a capacitor dielectric 136 located over the bottom capacitor plate 130. The dielectric layers 122 include a top dielectric layer 122a which extends to a top surface 137 of the capacitor dielectric 136. The top dielectric layer 122a includes a silicon dioxide-based dielectric material, and has a dielectric constant less than 4.1.

A high dielectric layer 140 is formed on the dielectric layers 122, contacting the top dielectric layer 122a. The high dielectric layer 140 includes at least a first sublayer 142 with a first dielectric constant higher than the dielectric constant of the top dielectric layer 122a. The first dielectric constant may be 6.5 to 9.0, for example. The first sublayer 142 may include silicon nitride. The first sublayer 142 may have a thickness of 200 nanometers to 1200 nanometers. The first sublayer 142 may be formed by a PECVD process using bis(tertiary-butyl-amino)silane (BTBAS), or a combination of dichlorosilane and ammonia, for example.

In this example, the high dielectric layer 140 may include a second sublayer 144 that is formed over the dielectric layers 122 prior to forming the first sublayer 142. The second sublayer 144 has a second dielectric constant that is lower than the first dielectric constant and higher than the dielectric constant of the top dielectric layer 122a. The second dielectric constant may be 4.5 to 6.5, for example. The second sublayer 144 may include silicon oxynitride. The second sublayer 144 may have a thickness of 100 nanometers to 700 nanometers. The second sublayer 144 may be formed by a PECVD process using a combination of BTBAS and TEOS, or a combination of dichlorosilane and nitrous oxide, for example.

Instances of the vias 126 are subsequently formed through the high dielectric layer 140 and the top dielectric layer 122a to make electrical connections to underlying instances of the interconnects 120. top level interconnects 124 are formed on the high dielectric layer 140, making electrical connections to the contacts 116 that extend through the high dielectric layer 140. A top capacitor plate 132 is formed directly above the bottom capacitor plate 130, concurrently with the top level interconnects 124. The top capacitor plate 132 has a lower corner 133 contacting the high dielectric layer 140 at a perimeter of the top capacitor plate 132. The top level interconnects 124 and the top capacitor plate 132 may be formed by an etched aluminum process, a copper damascene process, or a plated copper process, as disclosed in reference to the first level interconnects 118 and the additional levels of interconnects 120. Other methods for forming the top level interconnects 124 and the top capacitor plate 132 are within the scope of this example.

The top capacitor plate 132, the high dielectric layer 140 between the top capacitor plate 132 and the capacitor dielectric 136, the capacitor dielectric 136, and the bottom capacitor plate 130 provide a capacitor structure 104 of the microelectronic device 100. The capacitor structure 104 may be operated at a high voltage, for example, 300 volts to 1500 volts or 424 volts to 2121 volts peak. A thickness 138 of the capacitor dielectric 136 is at least 2 microns, and may be determined by a desired operating voltage of the top capacitor plate 132 relative to the bottom capacitor plate 130. For example, a version of the capacitor structure 104 in which the top capacitor plate 132 is designed to operate at 1000 volts may have a capacitor dielectric 136 with a thickness 138 of 16 microns to 20 microns. The bottom capacitor plate 130 may be capacitively coupled to the semiconductor material 102, and may be electrically connected to low voltage circuits, not shown, in the microelectronic device 100. During operation of the microelectronic device 100, high voltage signals applied to the top capacitor plate 132 may be sufficiently reduced in voltage by the capacitor structure 104 in series with the capacitance between the bottom capacitor plate 130 and the semiconductor material 102, so that the bottom capacitor plate 130 may provide the reduced voltage signals to the low voltage circuits.

Instances of the contacts 116, first level interconnects 118, vias 126, interconnects 120, and top level interconnects 124 may be configured to surround the capacitor structure 104, providing a faraday cage 108 that shields the top capacitor plate 132 from the low voltage components 106. While four levels of interconnects 118, 120, and 124 are shown in FIG. 1A, the number of interconnect levels varies depending on the application. Commonly, between 3 and 6 levels of interconnects are used.

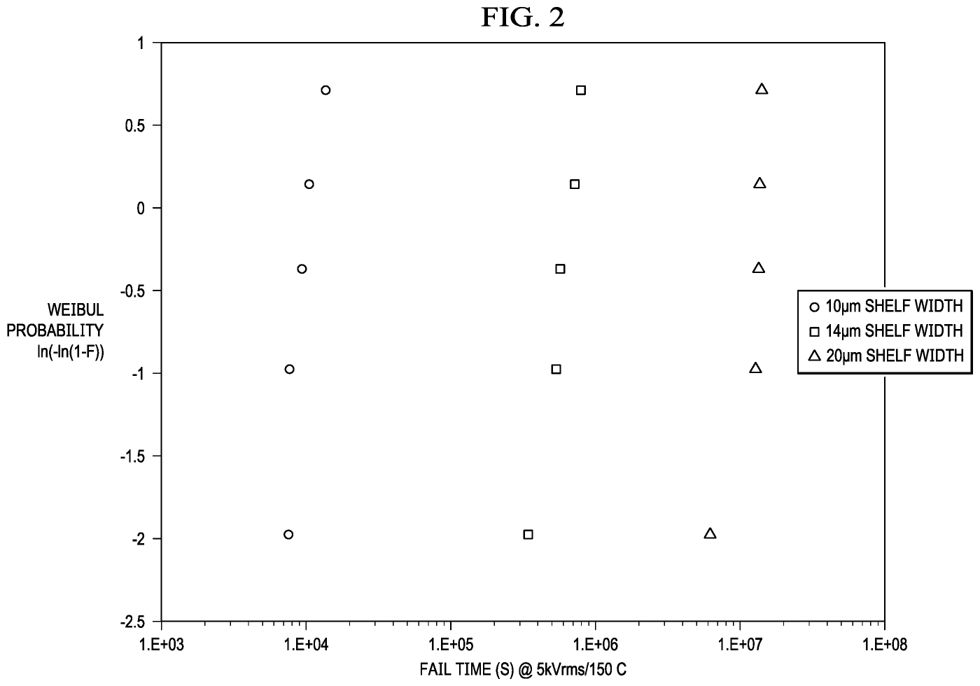

An electric field abatement structure 150 surrounding the top capacitor plate 132 is formed by removing the first sublayer 142 in an isolation break 152 of the electric field abatement structure 150. The isolation break 152 has an isolation width 154 which is at least 1 micron, and may be 14 microns to 25 microns to advantageously provide process margin in a lithographic process for forming the isolation break 152. The high dielectric layer 140 between the isolation break 152 and the lower corner 133 provides a shelf 155 of the electric field abatement structure 150. The high dielectric layer 140 is intact in the shelf 155; that is, the shelf 155 is free of breaks in the first sublayer 142 and the second sublayer 144. An electric field around the lower corner 133, when the top capacitor plate 132 is biased with respect to the bottom capacitor plate 130, is reduced by the high dielectric layer 140 having a higher dielectric constant than the top dielectric layer 122a, enabling the top capacitor plate 132 to be biased to a higher potential compared to a similar device without a high dielectric layer 140. The shelf 155 has a shelf width 146 of at least 14 microns. The shelf width 146 has a significant effect on the breakdown potential of the capacitor structure 104. There is an unexpected non-linear dependence of a breakdown potential of the capacitor structure 104 as a function of the shelf width 146, with values of the shelf width 146 of 14 microns or above showing significantly enhancing the breakdown potential of the capacitor structure 104. A shelf width 146 of 14 microns shows average Time Dependent Dielectric Breakdown (TDDB) values more than 50 times that of a shelf width 146 of 10 microns. Increasing the shelf width 146 to 20 microns results in an increase in the average TDDB failure time to more than 20 times that of a shelf width 146 of 14 microns. The TDDB data is shown in FIG. 2 and was collected at 6 kVrms and 150 C. Having the shelf width 146 of 14 microns or above may advantageously enable the capacitor structure 104 to be operated at a potential close to a breakdown potential of the capacitor dielectric 136, rather than being limited by breakdown around the lower corner 133.

The isolation break 152 may advantageously reduce leakage current from the top capacitor plate 132 to adjacent instances of the top level interconnects 124 through a conduction band well or a valence band well in the high dielectric layer 140. The conduction band well may be produced when the top capacitor plate 132 is biased to a positive potential with respect to the bottom capacitor plate 130, due to an effective band gap of the first sublayer 142 being lower than an effective band gap of the top dielectric layer 122a. The valence band well may be produced when the top capacitor plate 132 is biased to a negative potential with respect to the bottom capacitor plate 130, again due to the effective band gap of the first sublayer 142 being lower than the effective band gap of the top dielectric layer 122a.

A first protective overcoat (PO) layer 156 of inorganic dielectric material, such as one or more layers of silicon oxynitride or silicon nitride, is formed over the top level interconnects 124, the top capacitor plate 132, and the high dielectric layer 140. The first PO layer 156 may overlap partway onto the top capacitor plate 132, as depicted in FIG. 1A, to advantageously reduce dielectric breakdown around a perimeter of the top capacitor plate 132. The first PO layer 156 may expose the top capacitor plate 132 in a bond area 158.

A second PO layer 160 of polymer material, such as polyimide, benzocyclobutene (BCB), or polybenzoxazole (PBO), may be formed over the first PO layer 156. The second PO layer 160 also exposes the top capacitor plate 132 in the bond area 158. During assembly of the microelectronic device 100, an electrical connection 162 is made to the top capacitor plate 132. The electrical connection 162 may be implemented as a wire bond, as depicted in FIG. 1A. Other implementations of the electrical connection 162 are within the scope of this example.

FIG. 1B shows a detailed view of the portion of the microelectronic device 100 in the area of the electric field abatement structure 150. In this example, at least a portion of the second sublayer 144 extends continuously across the isolation break 152, as depicted in FIG. 1B. Measurements of breakdown potential have shown that having the second sublayer 144 in the isolation break 152 advantageously increases the breakdown potential compared to a similar electric field abatement structure 150 in which the second sublayer 144 is removed from the isolation break 152.

The electric field abatement structure 150 of this example may be formed by forming an etch mask, not shown, over the high dielectric layer 140 and top level interconnects 124 that exposes the first sublayer 142 in an area for the isolation break 152. The first sublayer 142 is completely removed by an etch process where exposed by the etch mask, forming the isolation break 152. The etch process is performed so as to leave at least the portion of the second sublayer 144 extending continuously across the isolation break 152. The etch process may include a reactive ion etch (RIE) process or a downstream etch process using fluorine and oxygen radicals that is selective to the silicon nitride in the first sublayer 142 with respect to the silicon oxynitride in the second sublayer 144. The etch process may be a timed etch process, carried out long enough to completely remove the first sublayer 142 and terminated to leave the portion of the second sublayer 144. Alternatively, the etch process may be an endpointed etch process, in which an optical emission band characteristic of carbon-oxygen radicals is monitored to determine when removal of silicon oxynitride has begun, enabling the etch process to be terminated while leaving the portion of the second sublayer 144. The etch mask is removed after the isolation break 152 is formed.

In another version of this example, the isolation break 152 may be formed before forming the top level interconnects 124 and the top capacitor plate 132. Forming the isolation break 152 before forming the top level interconnects 124 and the top capacitor plate 132 may simplify forming the etch mask, due to the substantial flat topography of the microelectronic device 100 before the top level interconnects 124 and the top capacitor plate 132 are formed.

FIG. 1C shows a detailed view of a portion of the microelectronic device 100 in the area of another electric field abatement structure 150. In this example, the second sublayer 144 is completely removed from the isolation break 152, as depicted in FIG. 1C. The electric field abatement structure 150 of this example may be formed by forming an etch mask, not shown, over the high dielectric layer 140 that exposes the first sublayer 142 in an area for the isolation break 152. The first sublayer 142 is completely removed by a first etch process where exposed by the etch mask, and the second sublayer 144 is completely removed by a second etch process where exposed by the first sublayer 142, forming the isolation break 152. The first etch process may be similar to the etch process disclosed in reference to FIG. 1B. The second etch process may reduce the oxygen radicals to increase an etch rate of the silicon oxynitride in the second sublayer 144. The second etch process may be a timed etch process, or may be an endpointed etch process. The second etch process may remove a portion of the top dielectric layer 122a, as depicted in FIG. 1C. The etch mask is removed after the first sublayer 142 is etched from the isolation break 152.

In one version of this example, the isolation break 152 may be formed after forming the top level interconnects 124 and the top capacitor plate 132. In another version of this example, the isolation break 152 may be formed before forming the top level interconnects 124 and the top capacitor plate 132.

FIG. 1D shows a detailed view of a portion of the microelectronic device 100 in the area of another example electric field abatement structure 150. In this example, an auxiliary high dielectric layer 164 extends on the shelf 155 and partway on the top capacitor plate 132, covering the lower corner 133. The auxiliary high dielectric layer 164 has a dielectric constant higher than the dielectric constant of the top dielectric layer 122a. The dielectric constant of the auxiliary high dielectric layer 164 may be higher than a dielectric constant higher of the first PO layer 156. The auxiliary high dielectric layer 164 may advantageously increase a breakdown potential of the capacitor structure 104 by reducing the electric field around the perimeter of the top capacitor plate 132. The isolation break 152 may be free of the auxiliary high dielectric layer 164, as depicted in FIG. 1D.

The electric field abatement structure 150 of this example may be formed by forming the auxiliary high dielectric layer 164 over the top level interconnects 124 and the top capacitor plate 132. An etch mask, not shown, is formed over the auxiliary high dielectric layer 164, exposing the auxiliary high dielectric layer 164 in an area for the isolation break 152. The auxiliary high dielectric layer 164 and the first sublayer 142 are completely removed by one or more etch processes, where exposed by the etch mask, forming the isolation break 152. The second sublayer 144 may be completely removed by the etch processes, where exposed by the first sublayer 142, as depicted in FIG. 1D. Alternatively, at least a portion of the second sublayer 144 may be left in the isolation break 152. The etch mask is subsequently removed. After the electric field abatement structure 150 is formed, the first PO layer 156 is formed on the auxiliary high dielectric layer 164. The first PO layer 156 and the auxiliary high dielectric layer 164 are removed from the bond area 158.

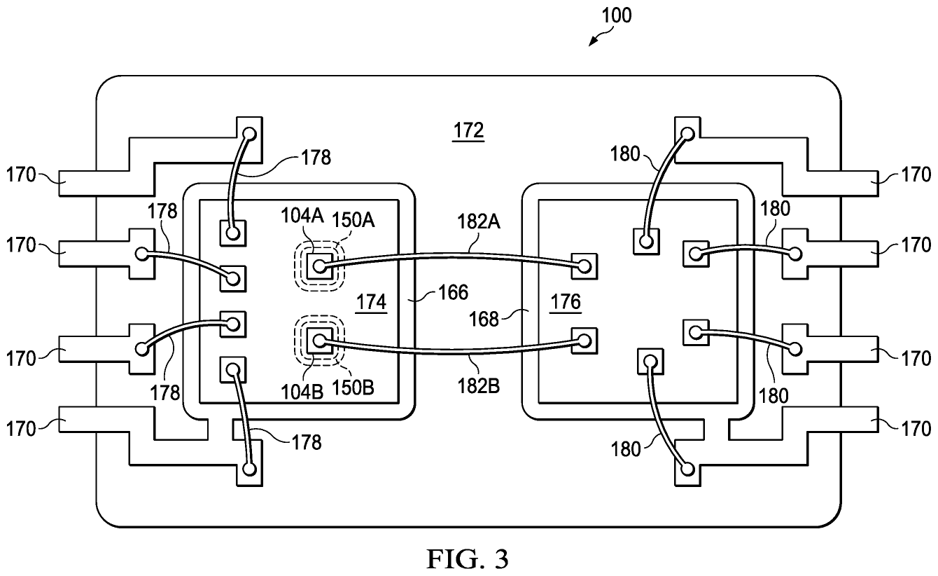

FIG. 3 is a top view of an example of the microelectronic device 100 implemented as a multi-ship module. The microelectronic device 100 of this example includes a first die pad 166 and a second die pad 168. The first die pad 166 and the second die pad 168 are electrically isolated from each other. The microelectronic device 100 of this example also includes external leads 170. The first die pad 166, the second die pad 168, and the external leads 170 may be parts of a lead frame, with an encapsulation material 172, as depicted in FIG. 3. Alternatively, the first die pad 166, the second die pad 168, and the external leads 180 may be parts of a chip carrier.

A low voltage die 174 containing capacitor structures 104A and 104B is attached to the first die pad 166. A high voltage die 176 of the microelectronic device 100 is attached to the second die pad 168. The low voltage die 174 is electrically coupled to instances of the external leads 170 through first wire bonds 178, as depicted in FIG. 3, or though ribbon bonds, solder bumps, or such. The high voltage die 176 is similarly electrically coupled to other instances of the external leads 170 through second wire bonds 180 or such. The high voltage die 176 is electrically coupled to the capacitor structures 104A and 104B through one or more high voltage wire bonds 182A and 182B. While the multi-chip module depicted in FIG. 3 contains two capacitor structures 104A and 104B, it can contain a single capacitor structure, or more than two capacitor structures depending on the use conditions.

During operation of the microelectronic device 100, the high voltage die 176 may be operated at a high voltage, for example, 300 volts to 1200 volts, while the low voltage die 174 is operated at low voltage, that is, less than 30 volts. The capacitor structures 104A and 104B may enable signals to be sent from the high voltage die 176 to the low voltage die 174 through the high voltage wire bonds 182A and 182B. The electric field abatement structures 150A and 150B may advantageously enable operation of the capacitor structures 104A and 104B at the operating potential of the high voltage die 176 and thus enable transfer of the signal to the low voltage die 174 without the necessity of a high voltage coupling capacitor on the high voltage die 176 to reduce the potential on the high voltage wire bonds 182A and 182B.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a substrate;
a bottom capacitor plate over the substrate;
dielectric layers above the bottom capacitor plate, the dielectric layers including a capacitor dielectric directly over the bottom capacitor plate, the dielectric layers including a top dielectric layer extending to a top surface of the capacitor dielectric, opposite from the bottom capacitor plate;
a high dielectric layer on the top dielectric layer, the high dielectric layer including at least a first sublayer having a first dielectric constant that is higher than a dielectric constant of the top dielectric layer;
a top capacitor plate on the high dielectric layer, over the bottom capacitor plate, the top capacitor plate having a lower corner contacting the high dielectric layer;
an electric field abatement structure surrounding the top capacitor plate, the electric field abatement structure including:
a shelf of the high dielectric layer extending outward from the lower corner at least 14 microns, the shelf being free of breaks in the high dielectric layer; and
an isolation break in the high dielectric layer past the shelf, the isolation break being free of the first sublayer.

2. The microelectronic device of claim 1, wherein the high dielectric layer includes a second sublayer having a second dielectric constant, the second sublayer being between the first sublayer and the capacitor dielectric, the second dielectric constant being lower than the first dielectric constant and higher than the dielectric constant of the top dielectric layer.

3. The microelectronic device of claim 2, wherein the first sublayer includes silicon nitride and the second sublayer includes silicon oxynitride.

4. The microelectronic device of claim 2, wherein at least a portion of the second sublayer extends across the isolation break.

5. The microelectronic device of claim 2, wherein the isolation break is free of the second sublayer.

6. The microelectronic device of claim 2, wherein the electric field abatement structure includes a high dielectric overcoat layer that extends partway on the top capacitor plate and extends over the first sublayer on the shelf, the high dielectric overcoat layer having a third dielectric constant that is higher than the dielectric constant of the top dielectric layer.

7. The microelectronic device of claim 6, wherein the high dielectric overcoat layer includes a dielectric material selected from the group consisting of silicon nitride and silicon oxynitride.

8. The microelectronic device of claim 6, wherein the isolation break is free of the high dielectric overcoat layer.

9. The microelectronic device of claim 2, wherein the first sublayer is 200 nanometers to 1200 nanometers thick.

10. The microelectronic device of claim 2, wherein the second sublayer is 100 nanometers to 700 nanometers thick.

11. The microelectronic device of claim 1, wherein the capacitor dielectric is 16 microns to 22 microns thick.

12. The microelectronic device of claim 1, further including an high voltage die separate from the substrate, the microelectronic device being free of a direct electrical connection between the high voltage die and the substrate, wherein a component of the high voltage die is directly electrically connected to the top capacitor plate.

13. A method of forming a microelectronic device, comprising:
forming a bottom capacitor plate over a substrate, the substrate including a semiconductor material;
forming dielectric layers above the bottom capacitor plate, the dielectric layers including a capacitor dielectric directly over the bottom capacitor plate, the dielectric layers including a top dielectric layer extending to a top surface of the capacitor dielectric, opposite from the bottom capacitor plate;
forming a high dielectric layer on the top dielectric layer, the high dielectric layer including at least a first sublayer having a first dielectric constant that is higher than a dielectric constant of the top dielectric layer;
forming a top capacitor plate on the high dielectric layer, the top capacitor plate having a lower corner contacting the high dielectric layer; and
forming an electric field abatement structure surrounding the top capacitor plate by removing the first sublayer in an isolation break of the electric field abatement structure, the isolation break being separated from the lower corner by at least 14 microns, the high dielectric layer between the isolation break and the lower corner providing a shelf of the electric field abatement structure.

14. The method of claim 13, wherein forming the high dielectric layer includes forming a second sublayer having a second dielectric constant over the top dielectric layer, before forming the first sublayer, the second dielectric constant being lower than the first dielectric constant and higher than the dielectric constant of the top dielectric layer.

15. The method of claim 14, wherein the first sublayer includes silicon nitride and the second sublayer includes silicon oxynitride.

16. The method of claim 14, wherein removing the first sublayer in the isolation break leaves at least a portion of the second sublayer extending continuously across the isolation break.

17. The method of claim 14, further including forming a high dielectric overcoat layer of the electric field abatement structure extending partway on the top capacitor plate and extending over the first sublayer on the shelf, the high dielectric overcoat layer having a third dielectric constant that is higher than the dielectric constant of the top dielectric layer.

18. The method of claim 17, further including removing the high dielectric overcoat layer in the isolation break.

19. The method of claim 14, wherein the first sublayer is 200 nanometers to 1200 nanometers thick and the second sublayer is 100 nanometers to 700 nanometers thick.

20. The method of claim 13, wherein the capacitor dielectric is 16 microns to 22 microns thick.
